(19) United States
(12) Patent Application Publication
(10) Pub. No.: US 2022/0102291 A1
(43) Pub. Date: Mar. 31, 2022

(54) POWER MODULE

(71) Applicant: Sharp Fukuyama Semiconductor Co., Ltd., Fukuyama City (JP)

(72) Inventors: Hiroki KANAI, Fukuyama City (JP); Naomichi FUJII, Fukuyama City (JP)

(21) Appl. No.: 17/489,064

(22) Filed: Sep. 29, 2021

(30) Foreign Application Priority Data
Sep. 30, 2020 (JP) 2020-165671

(51) Int. Cl. H01L 23/64; H01L 25/07; H01L 23/367; H01L 23/498

(52) U.S. Cl. CPC H01L 23/642; H01L 25/072; H01L 23/49838; H01L 23/49822; H01L 23/3672

(57) ABSTRACT

A power module comprises a first switching element and a second switching element mounted on a multilayer substrate; and a bypass capacitor formed on the multilayer substrate, wherein the multilayer substrate includes, a first wiring line pattern connecting a first terminal and the bypass capacitor, a second wiring line pattern connecting a second terminal and a third terminal, and a third wiring line pattern connecting a fourth terminal and the bypass capacitor, and the power module further includes, a first electrically conductive member connecting a non-mounting surface of the first switching element and a first connection portion provided on the second wiring line pattern, and a second electrically conductive member connecting a non-mounting surface of the second switching element and a second connection portion provided on the third wiring line pattern.

### CROSS-REFERENCE TO RELATED APPLICATION

The present application claims priority from Japanese Application JP2020-165671, the content of which is hereby incorporated by reference into this application.

### BACKGROUND

### Field

An aspect of the disclosure relates to a power module provided with a plurality of switching elements mounted on a multilayer substrate.

### BACKGROUND ART

Some switching elements include an electrode on a non-mounting surface that opposes a mounting surface of a wiring line substrate. In the related art, the electrode on the non-mounting surface of the switching element is wire-bonded and connected to an electrode on the wiring line substrate, but wire bonding causes parasitic inductance that is not negligible, whereby ringing occurs at a switching response time. U.S. Pat. No. 10,720,330 discloses technology in which ringing at a switching response time is suppressed by disposing two electrically conductive connectors respectively connecting electrodes on the non-mounting surfaces of two switching elements to electrodes on a wiring line substrate.

However, in U.S. Pat. No. 10,720,380, one of the two electrically conductive connectors connecting the electrodes on the wiring line substrate and the electrodes on the non-mounting surfaces is present between the two switching elements. As a result, the distance between the switching elements increases and the distance between ends of a wiring line connecting terminals of the switching elements increases, thereby increasing the loop inductance of a power loop, which is a problem.

An aspect of the disclosure has been contrived in view of the problem described above, and an object of the disclosure is to achieve a power module capable of reducing loop inductance while eliminating the generation of parasitic inductance caused by wire bonding.

In order to solve the above problems, a power module according to an aspect of the disclosure includes: a first switching element and a second switching element mounted on a multilayer substrate; and a bypass capacitor formed on the multilayer substrate for forming a power loop of the first switching element and the second switching element. A first terminal and a second terminal of the first switching element, and a third terminal and a fourth terminal of the second switching element are disposed to be aligned in the order of the first terminal, the second terminal, the third terminal, and the fourth terminal. The multilayer substrate includes a first wiring line pattern connecting the first terminal and the bypass capacitor, a second wiring line pattern connecting the second terminal and the third terminal, and a third wiring line pattern connecting the fourth terminal and the bypass capacitor. The power module further includes: a first electrically conductive member connecting a non-mounting surface of the first switching element and a first connection portion provided or the second wiring line pattern and located on a side different from the second terminal side with respect to the first terminal; and a second electrically conductive member connecting a non-mounting surface of the second switching element and a second connection portion provided on the third wiring line pattern and located on a side different from the third terminal side with respect to the fourth terminal.

In order to solve the above problems, a power module according to another aspect of the disclosure includes: a first switching element and a second switching element mounted on a multilayer substrate; and a bypass capacitor formed on the multilayer substrate for forming a power loop of the first switching element and the second switching element. A first terminal and a second terminal of the first switching element, and a third terminal and a fourth terminal of the second switching element are disposed to be aligned in the order of the second terminal, the first terminal, the third terminal, and the fourth terminal. The multilayer substrate includes a first wiring line pattern connecting the first terminal and the bypass capacitor, a second wiring line pattern connecting the second terminal and the third terminal, and a third wiring line pattern connecting the fourth terminal and the bypass capacitor. The power module further includes: a first electrically conductive member connecting a non-mounting surface of the first switching element and a first connection portion provided on the second wiring line pattern and located on a side different from the first terminal side with respect to the second terminal; and a second electrically conductive member connecting a non-mounting surface of the second switching element and a second connection portion provided on the third wiring line pattern and located on a side different from the third terminal side with respect to the fourth terminal.

### ADVANTAGE EFFECTS OF DISCLOSURE

A power module of an aspect of the disclosure is capable of reducing loop inductance while eliminating the generation of parasitic inductance caused by wire bonding.

### BRIEF DESCRIPTION OF THE DRAWINGS

FIG. 1 is a circuit configuration diagram of a power module according to a first embodiment.

FIG. 2 is a graph showing response waveforms of a current and a voltage between a first terminal and a second terminal of a first switching element.

FIG. 3 is a diagram illustrating connection between a non-mounting surface of a switching element and a wiring line pattern of a wiring line substrate according to a known technique.

FIG. 4 is a diagram illustrating connection between a non-mounting surface of a switching element and a wiring line pattern according to the first embodiment.

FIG. 5 is a cross-sectional view of a multilayer substrate of a power module according to the first embodiment.

FIG. 6 is a wiring line pattern diagram of a power module according to the first embodiment.

FIG. 7 is a wiring line pattern diagram of a power module according to the first embodiment.

FIG. 8 is a wiring line pattern diagram of a power module according to the first embodiment.

FIG. 9 is a cross-sectional view of a multilayer substrate of a power module according to a second embodiment.

FIG. 10 is a wiring line pattern diagram of a power module according to the second embodiment.

FIG. 11 is a wiring line pattern diagram of a power module according to the second embodiment.

FIG. 12 is a wiring line pattern diagram of a power module according to the second embodiment.

FIG. 13 is a cross-sectional view of a multilayer substrate of a power module according to a modification example of the second embodiment.

FIG. 14 is a wiring line pattern diagram of a power module according to a modification example of the second embodiment.

FIG. 15 is a wiring line pattern diagram of a power module according to a modification example of the second embodiment.

FIG. 16 is a wiring line pattern diagram of a power module according to a modification example of the second embodiment.

FIG. 17 is a cross-sectional view of a multilayer substrate of a power module according to a third embodiment.

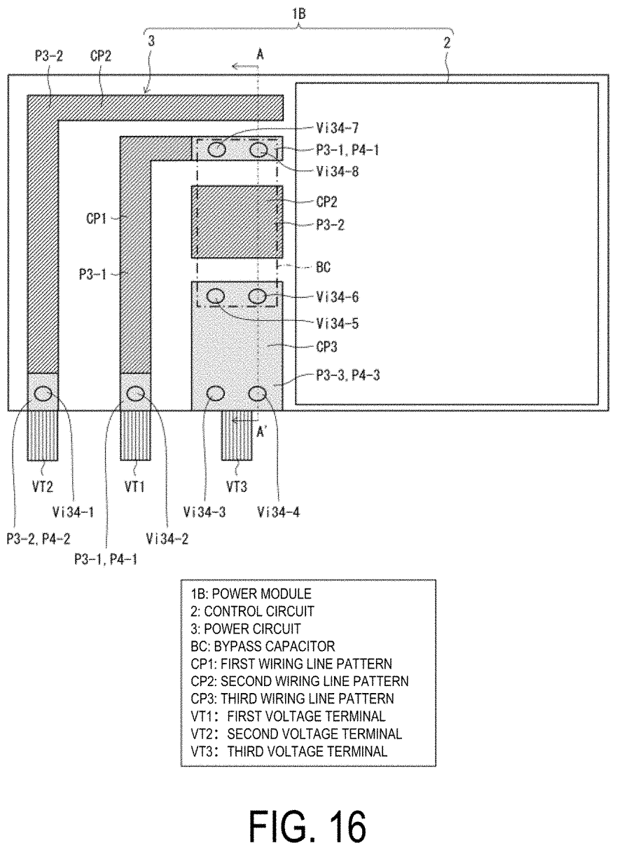

FIG. 16 is a cross-sectional view of a multilayer substrate of a power module according to the third embodiment.

FIG. 19 is a wiring line pattern diagram of a power module according to the third embodiment.

FIG. 20 is a wiring line pattern diagram of a power module according to the third embodiment.

FIG. 21 is a wiring line pattern diagram of a power module according to the third embodiment.

FIG. 22 is a cross-sectional view of a multilayer substrate of a power module according to a fourth embodiment.

FIG. 23 is a wiring line pattern diagram of a power module according to the fourth embodiment.

### DESCRIPTION OF EMBODIMENTS

### First Embodiment

An embodiment of the disclosure will be described in detail below.

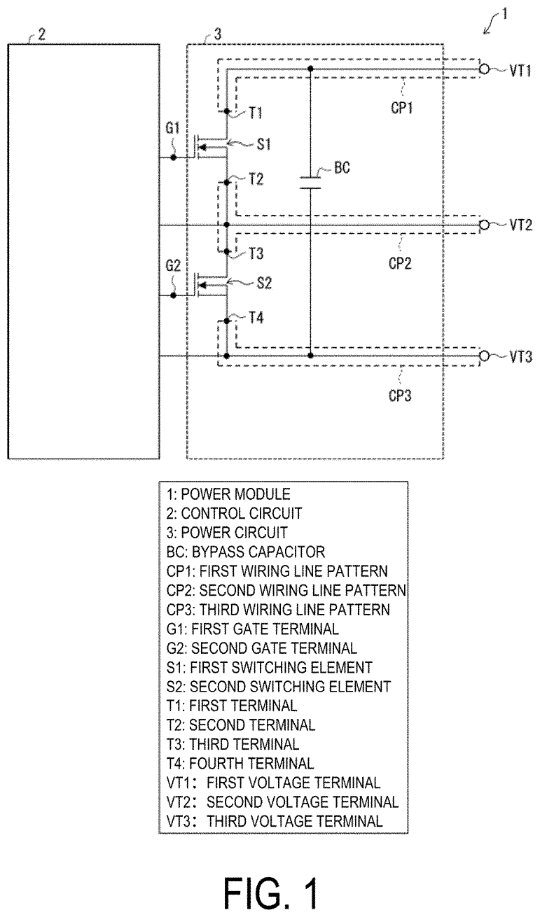

FIG. 1 illustrates a circuit configuration diagram of a power module 1 of a first embodiment of the disclosure.

The power module 1 is used for power conversion in industrial devices, in-vehicle devices, and consumer devices.

The power module 1 includes a control circuit 2 and a power circuit 3.

The control circuit 2 is disposed near the power circuit 3 and controls the power circuit 3. The control circuit 2 transmits a gate signal to a first switching element S1 of the power circuit 3. The control circuit 2 transmits a gate signal to a second switching element S2 of the power circuit 3. The gate signals applied to the first switching element S1 and the second switching element S2 are pulse signals in a range from 10 kHz to several MHz.

The power circuit 3 is provided with the first switching element S1 including a first gate terminal G1, a first terminal T1 and a second terminal T2, the second switching element S2 including a second gate terminal G2, a third terminal T3 and a fourth terminal T4, a bypass capacitor BC, a first voltage terminal VT1, a second voltage terminal VT2, and a third voltage terminal VT3.

The power circuit 3 includes a first wiring line pattern CP1 connected to the first voltage terminal VT1, a second wiring line pattern CP2 connected to the second voltage terminal VT2, and a third wiring line pattern CP3 connected to the third voltage terminal VT3.

The power circuit 3 controls currents of the first switching element S1 and the second switching element S2 based on the gate signals of the control circuit 2.

The first gate terminal G1 of the first switching element S1 and the second gate terminal G2 of the second switching element S2 are connected to the control circuit 2. The gate signals from the control circuit 2 are transmitted to the first switching element S1 and the second switching element S2 through the first gate terminal G1 and the second gate terminal G2, respectively. With this configuration, control is performed in such a manner that a current flowing between the first terminal T1 and the second terminal T2 of the first switching element S1 is allowed to flow or not allowed to flow, and control is performed in such a manner that a current flowing between the third terminal T3 and the fourth terminal T4 of the second switching element S2 is allowed to flow or not allowed to flow.

Examples of the first switching element S1 and the second switching element 32 include a gallium nitride high electron mobility transistor (GaN-HEMT) and a silicon carbide metal oxide semiconductor field effect transistor (SiC-MOSFET). The first terminal T1 of the first switching element S1 is a drain terminal, and the second terminal T2 thereof is a source terminal. The third terminal T3 of the second switching element S2 is a drain terminal, and the fourth terminal T4 thereof is a source terminal. Each of the first switching element S1 and the second switching element S2 may be an insulated gate bipolar transistor (IGBT). In this case, the first terminal T1 and the third terminal T3 are collector terminals, and the second terminal T2 and the fourth terminal T4 are emitter terminals.

The bypass capacitor BC has a function to remove noise generated in the power circuit 3.

The first terminal T1 of the first switching element S1 and one terminal of the bypass capacitor BC are connected to the first wiring line pattern CP1, and a first electric potential is input or output to the first voltage terminal VT1.

The second terminal T2 of the first switching element S1 and the third terminal T3 of the second switching element S2 are connected to the second wiring line pattern CP2 and are also connected to the control circuit 2, and a second electric potential is input or output to the second voltage terminal VT2.

The fourth terminal T4 of the second switching element S2 is connected to the third wiring line pattern CP3, the control circuit 2, and the other terminal of the bypass capacitor BC, and a third electric potential is input or output to the third voltage terminal VT3.

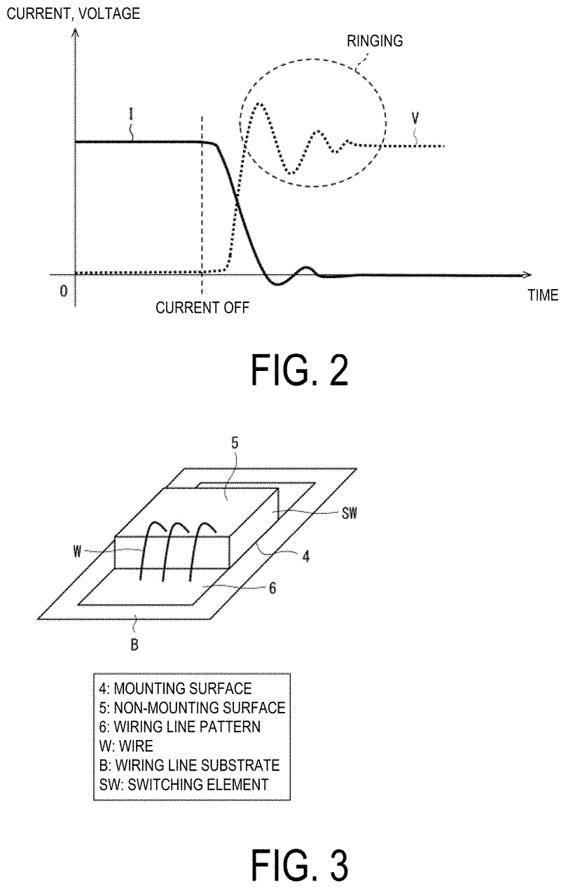

FIG. 2 depicts waveforms of a current I and a voltage V at the first terminal T1 and second terminal T2 of the first switching element S1 of the power module 1 illustrated in FIG. 1. When a parasitic inductance value of the power circuit 3 portion in FIG. 1 is large, ringing occurs at the rise time of the voltage V when the current of the first switching element S1 is stopped. In other words, when the first switching element S1 transitions from a current-on (conductive) state to a current-off (non-conductive state), ringing is generated in which a large voltage V is applied between the first terminal T1 and the second terminal T2 of the first switching element S1 due to parasitic inductance generated in the power circuit 3. The fall of the current I flowing between the first terminal T1 and the second terminal T2 becomes gradual.

As described above, when ringing occurs, the large voltage V is applied to the first switching element S1 and may damage the first switching element S1. When a switching element having a large withstand voltage is used in order to prevent such damage, the cost of components increases.

Since the fall of the current I flowing between the first terminal T1 and the second terminal T2 becomes gradual when the first switching element S1 transitions from the current-on state to the current-off state, the effect of switching loss is not negligible.

In the present embodiment, a countermeasure is taken to reduce the parasitic inductance of the power circuit 3 in order to suppress ringing generated at a high speed switching time and to reduce the switching loss.

FIG. 3 illustrates a state in which a switching element SW is mounted on a wiring line substrate B.

The switching element SW includes a mounting surface 4 that is mounted on the wiring line substrate B and a non-mounting surface 5 that is not mounted on the wiring line substrate B, and may include an electrode on the non-mounting surface 5 opposing the mounting surface 4 in some cases. This is because the reference electric potential of the switching element SW needs to be stabilized by electrically connecting the electrode on the non-mounting surface 5 with an electrode on a wiring line pattern 6 of the wiring line substrate B.

In the known technique, as illustrated in FIG. 3, the electrode on the non-mounting surface 5 of the switching element SW and the electrode on the wiring line pattern 6 of the wiring line substrate B are connected by a wire W.

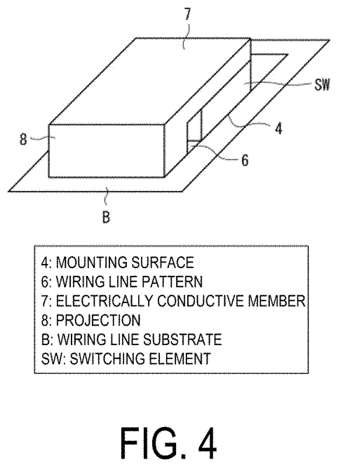

In the present embodiment, as illustrated in FIG. 4, an electrically conductive member 7 is disposed in contact with the entire surface of the electrode on the non-mounting surface 5 of the switching element SW, where a projection 8 is provided on the electrically conductive member 7, and a bottom face of the projection 8 is disposed in contact with the electrode of the wiring line pattern 6 of the wiring line substrate B. An example of the electrically conductive member 7 is a graphite sheet. The electrically conductive member 7 may be an electrically conductive paste such as a silver paste. The projection 8 may be made of the same material as the electrically conductive member 7 or made of a different material, provided that the projection 8 is electrically conductive. For example, the electrically conductive member 7 may be constituted by using a metal plate for the projection 8 and using a graphite sheet for portions other than the projection.

A method of electrically connecting the electrode on the non-mounting surface 5 and the electrode on the wiring line pattern 6 of the wiring line substrate B with the electrically conductive member 7 is such that the electrode on the non-mounting surface 5 and the electrode on the wiring line pattern 6 of the wiring line substrate B are connected by the electrically conductive member 7 having a wider connection area compared to the electrical connection method using the wire W. As a result, the density of a current that instantaneously flows when a electric potential difference is generated between the two electrodes may be made small and uniform, thereby making it possible to reduce parasitic inductance.

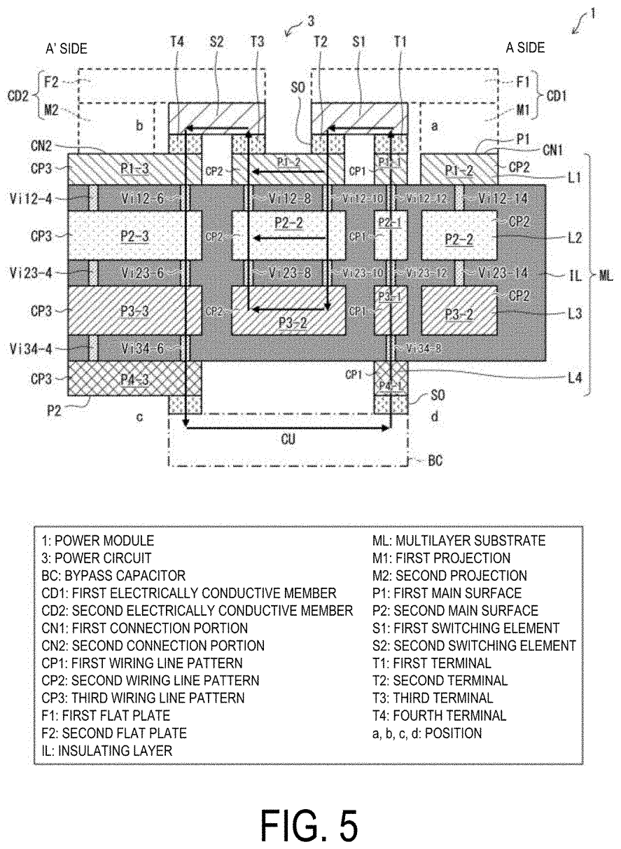

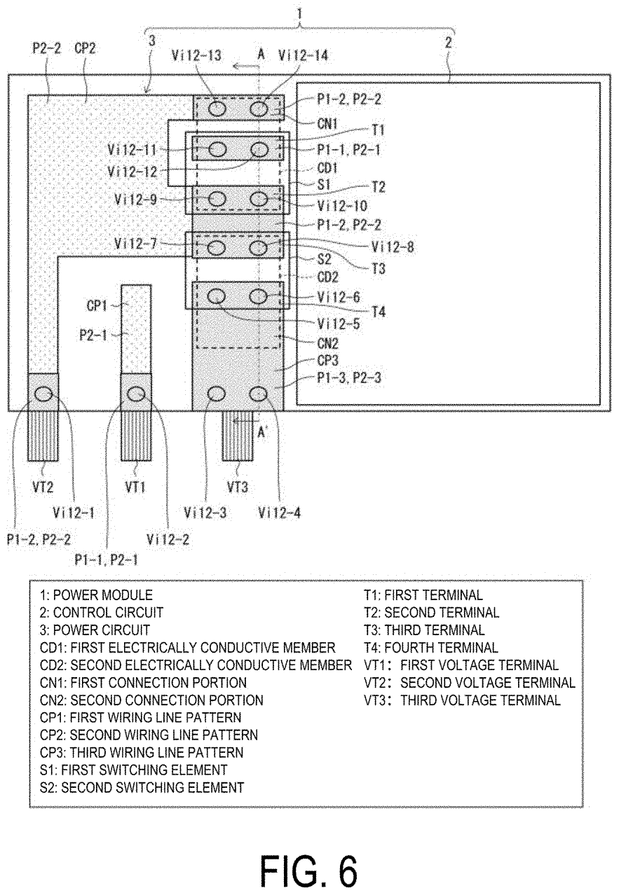

FIG. 5 illustrates a cross-sectional view of the power circuit 3 of the power module 1 according to the first embodiment taken along a line A-A′ indicated in FIG. 6. In the power circuit 3, the first switching element S1 and the second switching element S2 are connected, by a solder SO, to a first main surface P1 of a first layer L1, which is the uppermost surface of a multilayer substrate ML. A first electrically conductive member CD1 is placed on the first switching element S1.

The first electrically conductive member CD1 includes a first flat plate F1 in contact with the upper side of the first switching element S1, and a first projection M1 projecting from the first flat plate F1 toward the multilayer substrate ML to make contact with the second wiring line pattern CP2. The first flat plate F1 and the first projection M1 may be constituted of the same material or may be constituted of different materials. For example, the first electrically conductive member CD1 may be constituted by using a metal plate for the first projection M1 and using a graphite sheet for the first flat plate F1.

The first projection M1 of the first electrically conductive member CD1 is in contact with the first main surface P1.

A second electrically conductive member CD2 is set on the second switching element S2.

The second electrically conductive member CD2 includes a second flat plate F2 in contact with the upper side of the second switching element S2, and a second projection M2 projecting from the second flat plate F2 toward the multilayer substrate ML to make contact with the third wiring line pattern CP3. The second flat plate F2 and the second projection M2 may be constituted of the same material or may be constituted of different materials. For example, the second electrically conductive member CD2 may be constituted by using a metal plate for the second projection M2 and using a graphite sheet for the second flat plate F2.

The second projection M2 of the second electrically conductive member CD2 is in contact with the first main surface P1.

In the multilayer substrate ML, wiring line patterns of the first layer L1, a second layer L2, a third layer L3, and a fourth layer L4 are formed in the stated order from the first main surface P1, and an insulating layer IL is formed between the first and second layers L1 and L2, between the second and third layers L2 and L3, and between the third and fourth layers L3 and L4, and is also formed on side surfaces of the first, second, third, and fourth layers L1, L2, L3, and L4. A first layer-second layer connection via Vi12 is formed between the first layer L1 and the second layer L2 to establish an electrical connection between the first layer L1 and the second layer L2. A second layer-third layer connection via Vi23 is formed between the second layer L2 and the third layer L3 to establish an electrical connection between the second layer L2 and the third layer L3. A third layer-fourth layer connection via Vi34 is formed between the third layer L3 and the fourth layer L4 to establish an electrical connection between the third layer L3 and the fourth layer L4. The bypass capacitor BC is connected by the solder SO to a second main surface P2 of the fourth layer L4, which is the lowermost surface of the multilayer substrate ML. The inner layers of the multilayer substrate ML refer to the second layer L2 and the third layer L3, where the second layer L2 is called a first inner layer and the third layer L3 is called a second inner layer.

The arrows in FIG. 5 represent a current CU that flows through a current path existing in the multilayer substrate ML and indicating a loop in which the current is rapidly switched by a switching operation. The bypass capacitor BC is disposed at a position overlapping the first switching element S1 and the second switching element S2 when viewed from a direction perpendicular to the multilayer substrate ML. The current CU flowing through the first switching element S1 and the second switching element S2 flows in a direction from a position a toward a position b, while the current CU flowing through the bypass capacitor BC flows reversely in a direction from a position c toward a position d. As a result, the direction of a magnetic field due to the current CU flowing from the position a toward the position b and the direction of a magnetic field due to the current CU flowing from the position c toward the position d are reverse to each other, whereby the magnetic fields cancel each other out. Thus, loop inductance, which is the parasitic inductance brought about by the change in the current flowing through the first switching element S1 and the second switching element S2, is decreased.

Likewise, the current CU flowing perpendicularly with respect to the horizontal direction of the multilayer substrate ML, in other words, the current CU flowing in a direction from the position d toward the position a and the current CU flowing in a direction from the position b toward the position c are also reverse to each other in direction. As a result, the direction of the magnetic field due to the current CU flowing from the position d toward the position a and the direction of the magnetic field due to the current CU flowing from the position b toward the position c are reverse to each other, whereby the magnetic fields cancel each other out. Thus, the loop inductance, which is the parasitic inductance brought about by the change in the current flowing through the first switching element S1 and the second switching element S2, is decreased.

A first connection portion CN1, which is in contact with the first projection M1 of the first electrically conductive member CD1 disposed on the first switching element S1, is disposed on a side different, from the second terminal T2 side with respect to the first terminal T1.

A second connection portion CN2, which is in contact with the second projection M2 of the second electrically conductive member CD2 disposed on the second switching element S2, is disposed on a side different from the third terminal T3 side with respect to the fourth terminal T4.

As a result, since the second terminal T2 of the first switching element S1 and the third terminal T3 of the second switching element S2 may be disposed close to each other on the first main surface P1, the current path can be shortened. As described above, the current path extending around the power circuit 3 of the power module 1 can be shortened, and the loop inductance, which is the parasitic inductance, can be reduced.

FIGS. 6, 7, and 8 are each a wiring line pattern diagram of the power module 1 according to the first embodiment. As illustrated in FIGS. 5 to 8, the multilayer substrate ML of the power circuit 3 according to the power module 1 of the first embodiment includes the first wiring line pattern CP1, the second wiring line pattern CP2, and the third wiring line pattern CP3 described above with reference to FIG. 1.

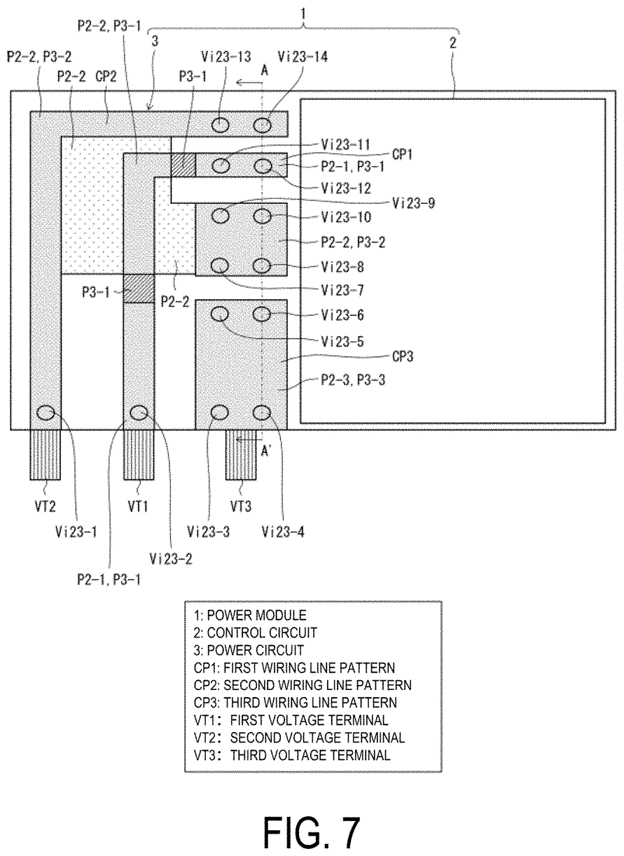

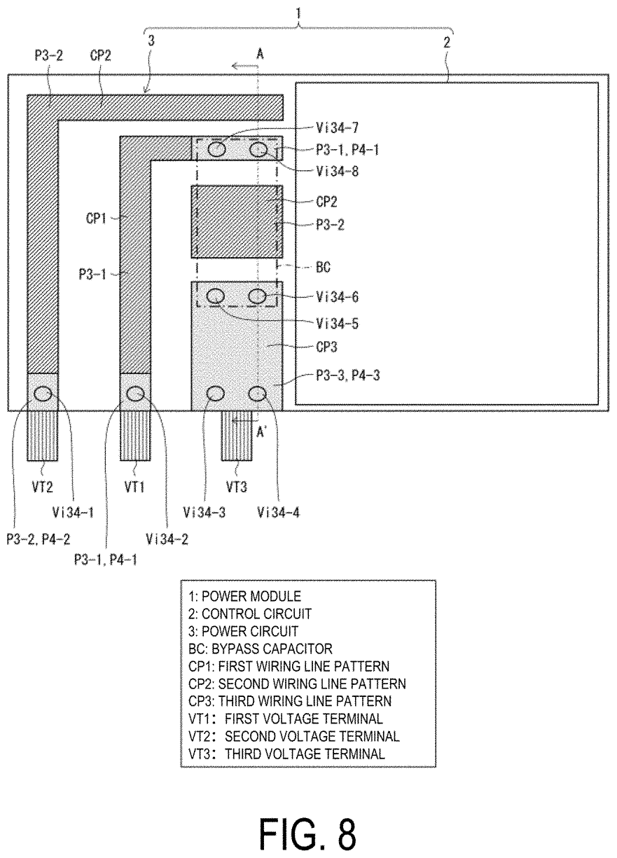

FIG. 6 illustrates shapes of wiring lines in the first layer L1 and the second layer L2. FIG. 7 illustrates shapes of wiring lines in the second layer L2 and the third layer L3. FIG. 8 illustrates shapes of wiring lines in the third layer L3 and the fourth layer L4. Note that in FIGS. 6, 7, and 8, two reference signs of patterns may be described next to each other; such a case indicates that wiring line patterns are formed in both of layers that overlap.

As illustrated in FIGS. 5 to 6, in order to connect the first terminal T1 of the first switching element S1 to the first voltage terminal VT1, the first wiring line pattern CP1 includes patterns P1-1, P2-1, P3-1 and P4-1, first layer-second layer connection vias Vi12-2, Vi12-11 and Vi12-12, second layer-third layer connection vias Vi23-2, Vi23-11 and Vi23-12, and third layer-fourth layer connection vias Vi34-2, Vi34-7 and Vi34-8.

As illustrated in FIGS. 5 to 8, in order to connect the second terminal T2 of the first switching element S1, the third terminal T3 of the second switching element S2, and the second voltage terminal VT2 to one another, the second wiring line pattern CP2 includes patterns P1-2, P2-2, P3-2 and P4-2, first layer-second layer connection vias Vi12-1, Vi12-13, Vi12-14, Vi12-9, Vi12-10, Vi12-7 and Vi12-8, second layer-third layer connection vias Vi23-1, Vi23-7, Vi23-8, Vi23-9, Vi23-10, Vi23-13 and Vi23-14, and a third layer-fourth layer connection via Vi34-1.

As illustrated in FIGS. 5 to 8, in order to connect the fourth terminal T4 of the second switching element S2 to the third voltage terminal VT3, the third wiring line pattern CP3 includes patterns P1-3, P2-3, P3-3 and P4-3, first layer-second layer connection vias Vi12-3, Vi12-4, Vi12-5 and Vi12-6, second layer-third layer connection vias Vi23-3, Vi23-4, Vi23-5 and Vi23-6, and third layer-fourth layer connection vias Vi34-3, Vi34-4, Vi34-5 and Vi34-6.

As described above, the power module 1 includes the first switching element S1 and the second switching element S2 mounted on the multilayer substrate ML, and the bypass capacitor BC formed on the multilayer substrate ML so as to form the power loop of the first switching element S1 and the second switching element S2.

The first terminal T1 and the second terminal T2 of the first switching element S1 and the third terminal T3 and the fourth terminal T4 of the second switching element S2 are disposed so as to be aligned in the following order: the first terminal T1, the second terminal T2, the third terminal T3, and the fourth terminal T4.

The multilayer substrate ML includes the first wiring line pattern CP1 connecting the first terminal T1 and the bypass capacitor BC, the second wiring line pattern CP2 connecting the second terminal T2 and the third terminal T3, and the third wiring line pattern CP3 connecting the fourth terminal T4 and the bypass capacitor BC.

The power module 1 further includes the first electrically conductive member CD1 that connects the non-mounting surface of the first switching element S1 and the first connection portion CN1 provided on the second wiring line pattern CP2 and located on the side different from the second terminal T2 side with respect to the first terminal T1, and the second electrically conductive member CD2 that connects the non-mounting surface of the second switching element S2 and the second connection portion CN2 provided on the third wiring line pattern CP3 and located on the side different from the third terminal T3 side with respect to the fourth terminal T4.

The first switching element S1 and the second switching element S2 are disposed on the first main surface P1 of the multilayer substrate ML. The bypass capacitor BC is disposed on the second main surface P2 of the multilayer substrate ML on the opposite side to the first main surface P1.

The first electrically conductive member CD1 is connected to the second wiring line pattern CP2 on the side opposite to the second terminal T2 side with respect to the first terminal T1.

The second wiring line pattern CP2 passes over the first main surface P1 of the multilayer substrate ML to connect the second terminal T2 and the third terminal T3.

The first terminal T1 and the third terminal T3 include drain terminals, and the second terminal T2 and the fourth terminal T4 include source terminals.

Actions and Effects

The first electrically conductive member CD1 is disposed on the first, switching element S1, and the first projection M1 of the first electrically conductive member CD1 is electrically connected to the second wiring line pattern CP2 having a second electric potential. This makes it possible to reduce the parasitic inductance of the power circuit 3.

The second electrically conductive member CD2 is disposed on the second switching element S2, and the second projection M2 of the second electrically conductive member CD2 is electrically connected to the wiring line pattern CP3 having a third electric potential. This makes it possible to reduce the parasitic inductance of the power circuit 3.

The first switching element S1 and the second switching element S2 are disposed side-by-side on the first main surface P1 of the first layer L1 of the multilayer substrate ML so that the current flows through the first terminal T1, the second terminal T2, the third terminal T3, and the fourth terminal T4 in that order, and the bypass capacitor BC is disposed on the second main surface P2 of the fourth layer L4 opposing the mounting surface of the first main surface P1. With this configuration, the current path of the power circuit 3 forms a power loop and the magnetic fields due to the current flowing through the current path cancel each other out. Thus, the loop inductance, which is the parasitic inductance, decreases.

The first projection M1 of the first electrically conductive member CD1 is brought into contact with the first connection portion CN1 of the second wiring line pattern CP2 disposed in a direction opposite to the second terminal T2 side with respect to the first terminal T1. In addition, the second projection M2 of the second electrically conductive member CD2 is brought into contact with the second connection portion CN2 of the third wiring line pattern CP3 disposed In a direction opposite to the third terminal T3 side with respect to the fourth terminal T4.

As a result, the second terminal T2 of the first switching element S1 and the third terminal T3 of the second switching element S2 can be brought close to each other and electrically connected. Thus, since the path of the current flowing through the power circuit 3 can be shortened, the loop inductance, which is the parasitic inductance, can be reduced.

According to the above-described countermeasures, the parasitic inductance of the power circuit 3 serving as the power module 1 can be reduced, so that the ringing at the switching response time may be suppressed and the switching loss can be reduced.

### Second Embodiment

Another embodiment of the disclosure will be described below. Note that, for convenience of explanation, components having a function identical to those in the above-described embodiment will be denoted by the same reference signs, and descriptions of those components will be omitted.

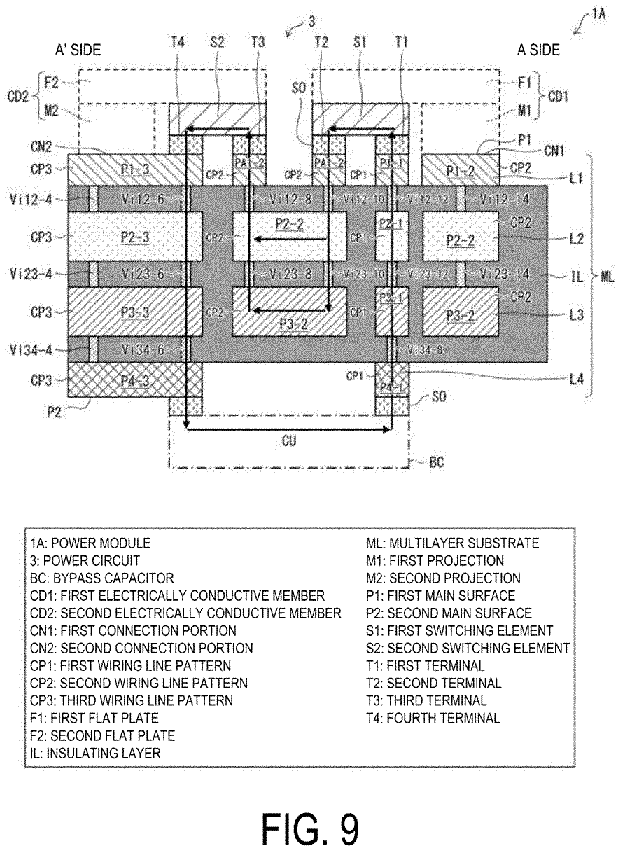

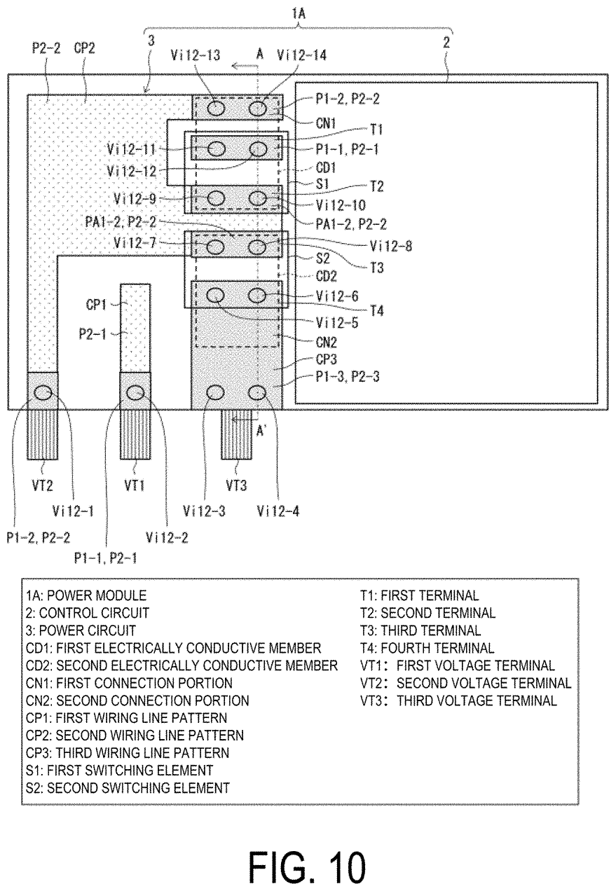

FIG. 9 is a cross-sectional view of the multilayer substrate ML of the power circuit 3 of a power module 1A according to a second embodiment, where a line A-A′ indicated in FIG. 10 is taken as a reference.

As illustrated in FIG. 9, the second terminal T2 of the first switching element S1 and the third terminal T3 of the second switching element S2 are not connected to each other at the first main surface P1, but are connected to each other at the second layer L2 and the third layer L3, which are inner layers.

The second terminal T2 and the third terminal T3 are connected to the second wiring line pattern CP2. Since high voltage application and connection to a ground electric potential are alternately carried out at the switching time, in a case where the above terminals are connected at the first main surface P1, a tracking phenomenon may occur due to creepage discharge when a sufficient creepage distance is not ensured between the first wiring line pattern CP1 and the second wiring line pattern CP2 and between the second wiring line pattern CP2 and the third wiring line pattern CP3, which increases the risk of burnout of the power module.

When the second terminal T2 and the third terminal T3 are not connected to each other at the first main surface P1, no tracking generating path is present on the first main surface P1, and therefore it is unnecessary to ensure a creepage distance. This makes it possible to shorten the distance between the wiring line patterns formed in a first layer L1 serving as the first main surface P1, as compared to the first embodiment. This allows the power module 1A to be made smaller.

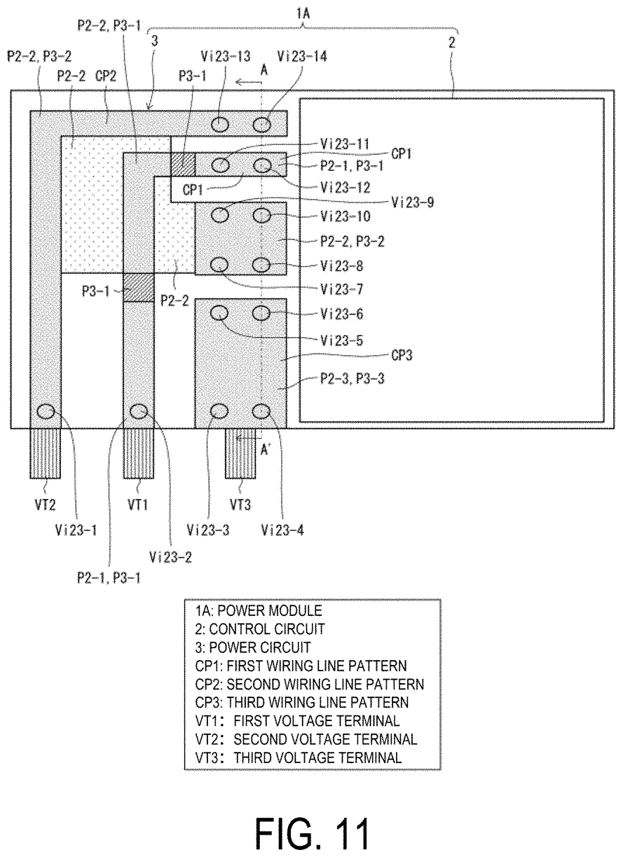

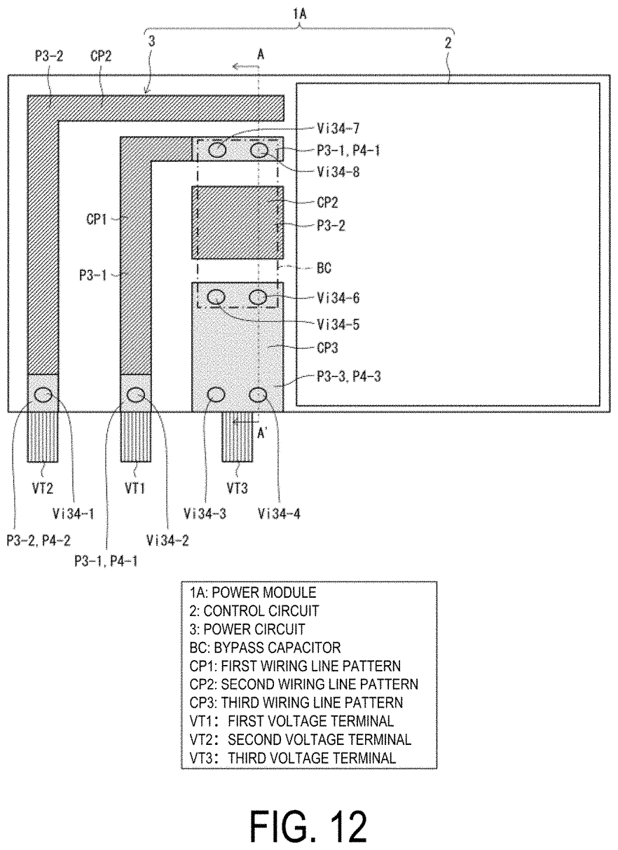

FIGS. 10, 11, and 12 are wiring line pattern diagrams of the power module 1A according to the second embodiment. FIG. 10 illustrates shapes of wiring lines in the first layer L1 and the second layer L2. FIG. 11 illustrates shapes of wiring lines in the second layer L2 and the third layer L3. FIG. 12 illustrates shapes of wiring lines in the third layer L3 and the fourth layer L4.

Only portions different from the first embodiment will be described, and a description of other portions will be omitted as these are the same as in the first embodiment.

The second terminal T2 of the first switching element S1 and the third terminal T3 of the second switching element S2 are not connected in the first layer L1 as indicated in the pattern PA1-2 of FIG. 10. As indicated in the pattern P2-2 and the pattern P3-2 in FIGS. 11 and 12, the above terminals are connected in the second layer L2 and the third layer L3, which are inner layers.

As described above, the multilayer substrate ML includes the second layer L2 and the third layer L3 representing a plurality of inner layers formed inside the multilayer substrate ML, and the second wiring line pattern CP2 extends through at least one of the plurality of inner layers so as to connect the second terminal T2 and the third terminal T3.

Modification Example of Second Embodiment

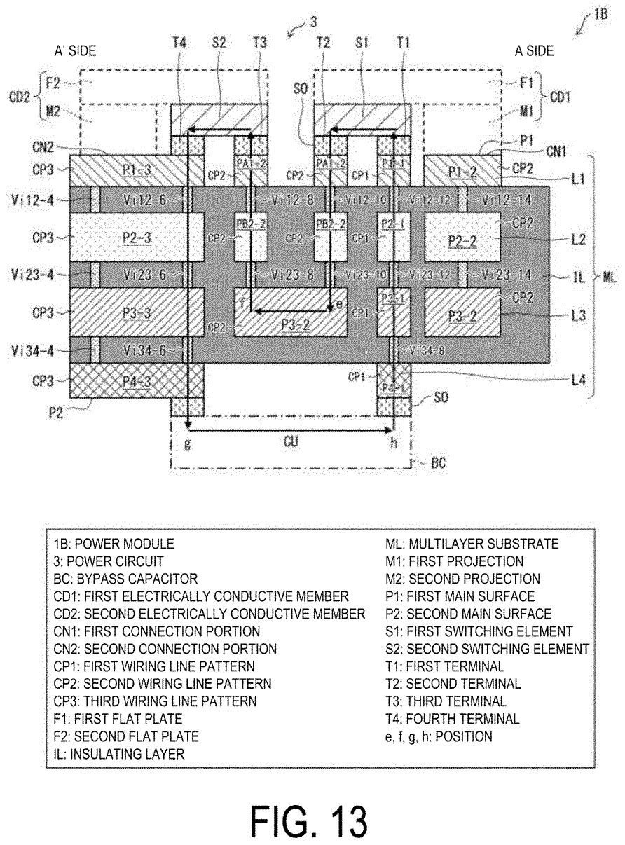

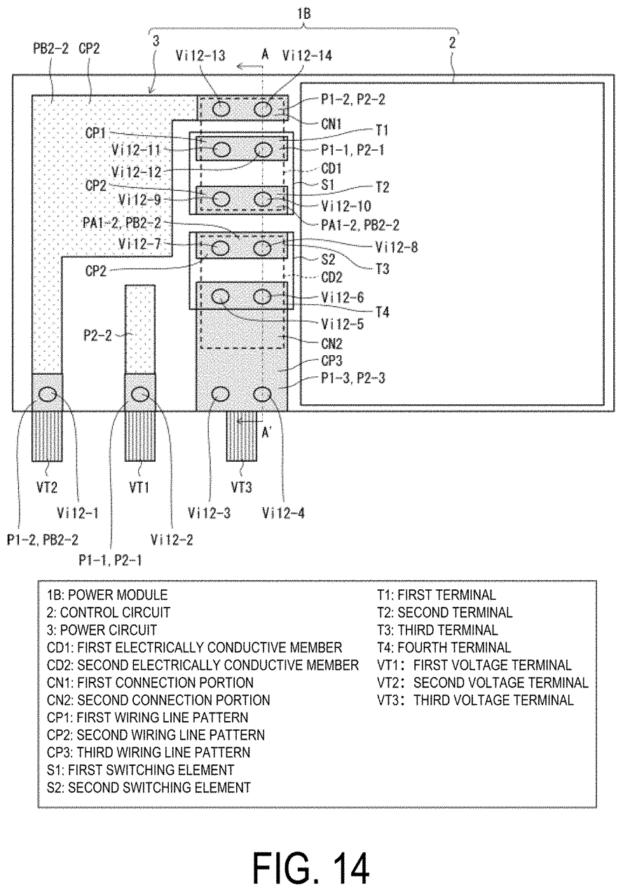

FIG. 13 is a cross-sectional view of the multilayer substrate ML of the power circuit 3 of a power module 1B according to a modification example of the second embodiment, where a line A-A′ indicated in FIG. 14 is taken as a reference. As illustrated in FIG. 13, the path of the current flowing through the multilayer substrate ML is indicated by arrows.

As illustrated in FIG. 13, the second terminal T2 of the first switching element S1 and the third terminal T3 of the second switching element S2 are connected neither in the first layer L1 nor in the second layer L2, which is an inner layer, but are connected in the third layer L3, which is closer to the fourth layer L4 than the second layer L2 and on which the bypass capacitor BC.

With this configuration, the path of a current flowing from a position e to a position f and the path of a current flowing from a position g to a position h become close to each other. In the present embodiment, since the current CU flows only in the third layer L3 near the fourth layer L4 compared to the second embodiment in which the current CU flows in the second layer L2 and the third layer L3, a magnetic field due to the current flowing from the position e to the position f and a magnetic field due to the current flowing from the position g to the position h further become close and strongly cancel each other out. This makes it possible to further reduce loop inductance, which is the parasitic inductance.

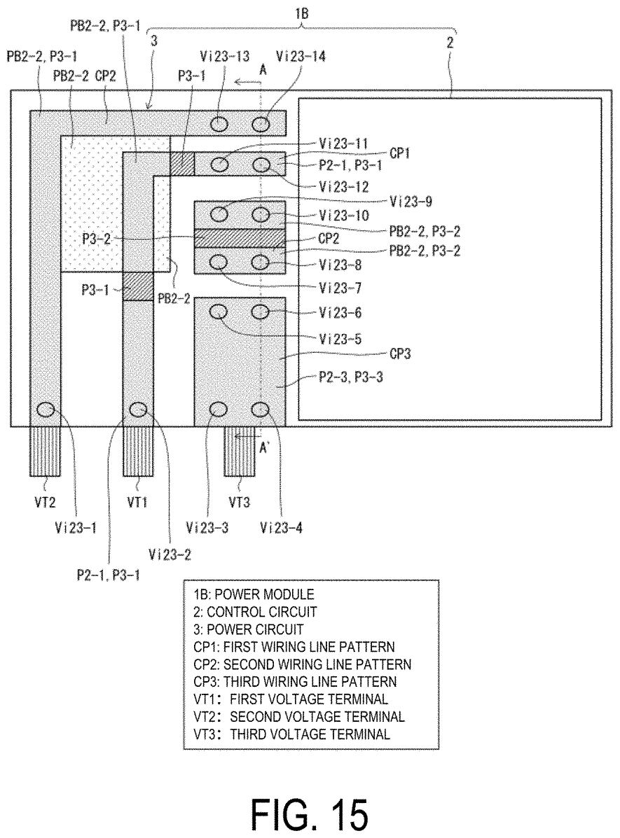

FIGS. 14, 15, and 16 are wiring line pattern diagrams of the power module 1B. FIG. 14 illustrates wiring line patterns in the first layer L1 and the second layer L2. FIG. 15 illustrates wiring line patterns in the second layer L2 and the third layer L3. FIG. 16 illustrates wiring line patterns in the third layer L3 and the fourth layer L4.

Only portions different from the second embodiment will be described, and a description of other portions will be omitted as these are the same as in the second embodiment.

As illustrated in patterns PA1-2 and PB2-2 in FIGS. 14 and 15, the second terminal T2 of the first switching element S1 and the third terminal T3 of the second switching element S2 are connected neither in the first layer L1 nor in the second layer L2, which is an inner layer, but are connected in the third layer L3, which is an inner layer, as illustrated in pattern P3-2 in FIGS. 15 and 16.

In this manner, the multilayer substrate ML includes the second layer L2 formed therein and the third layer L3 formed at a position further separated from the first switching element S1 and the second switching element S2 than the second layer L2, and the second wiring line pattern CP2 extends through the third layer L3 to connect the second terminal T2 and the third terminal T3 to each other.

### Third Embodiment

Another embodiment of the disclosure will be described below. Note that, for convenience of explanation, components having a function identical to those in the above-described embodiment will be denoted by the same reference signs, and descriptions of those components will be omitted.

Only portions different from the first embodiment will be described, and a description of other portions will be omitted as these are the same as in the first embodiment.

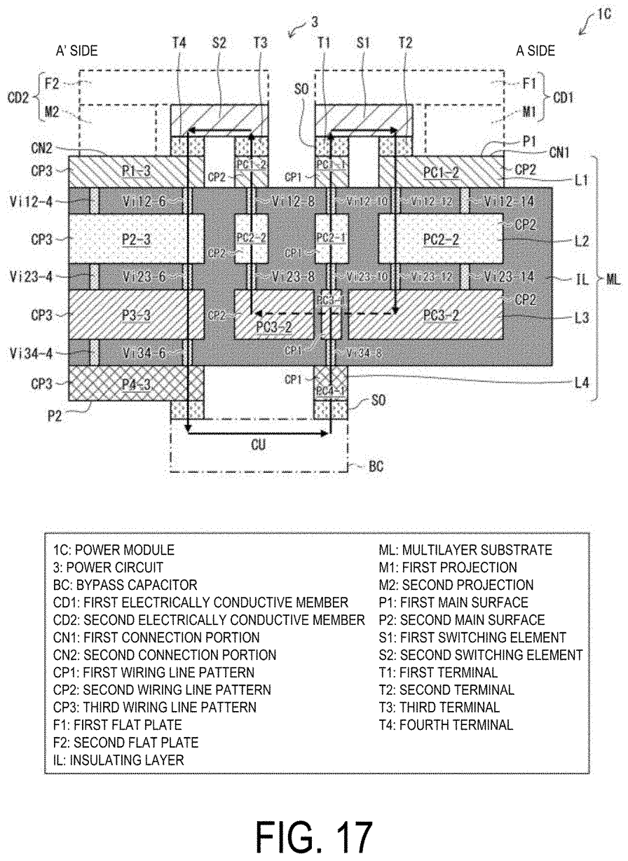

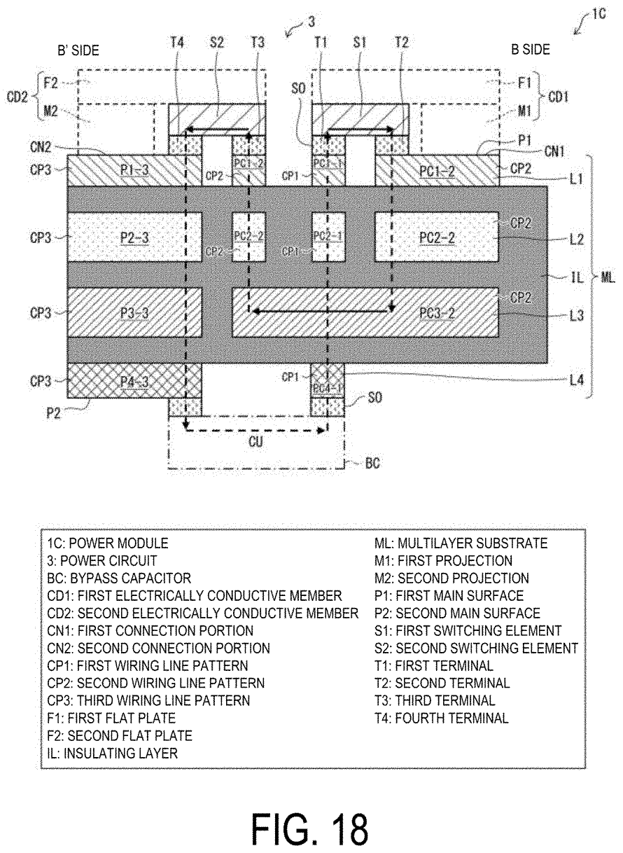

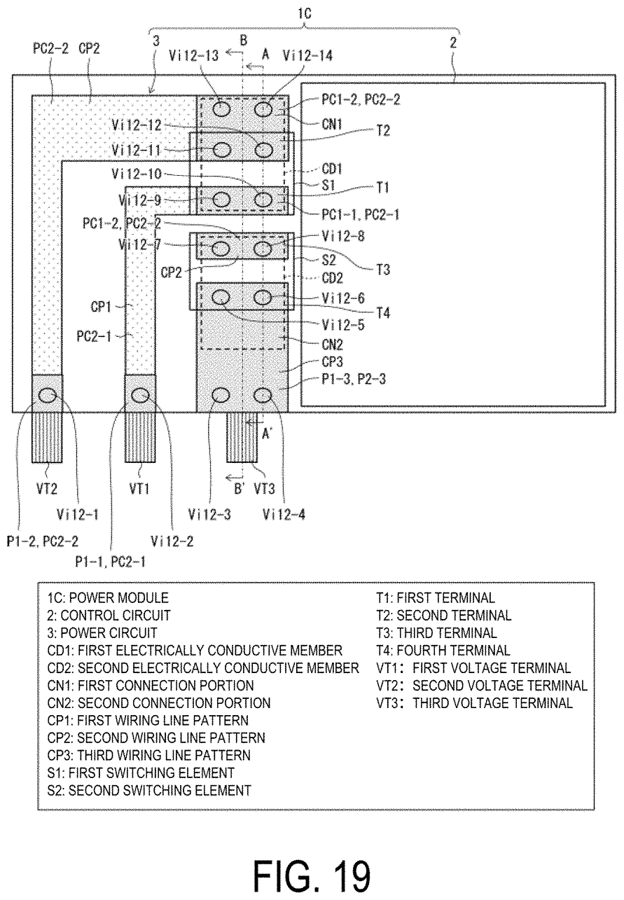

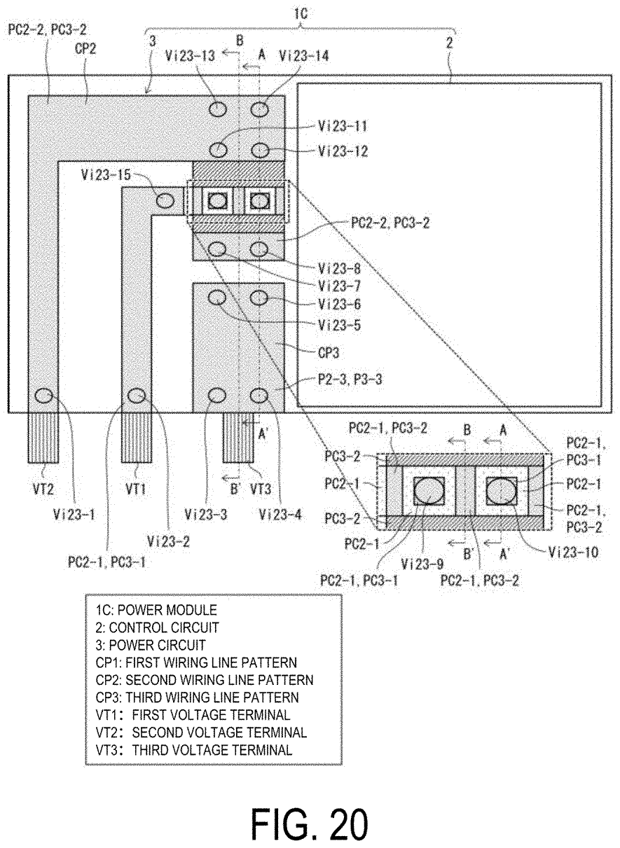

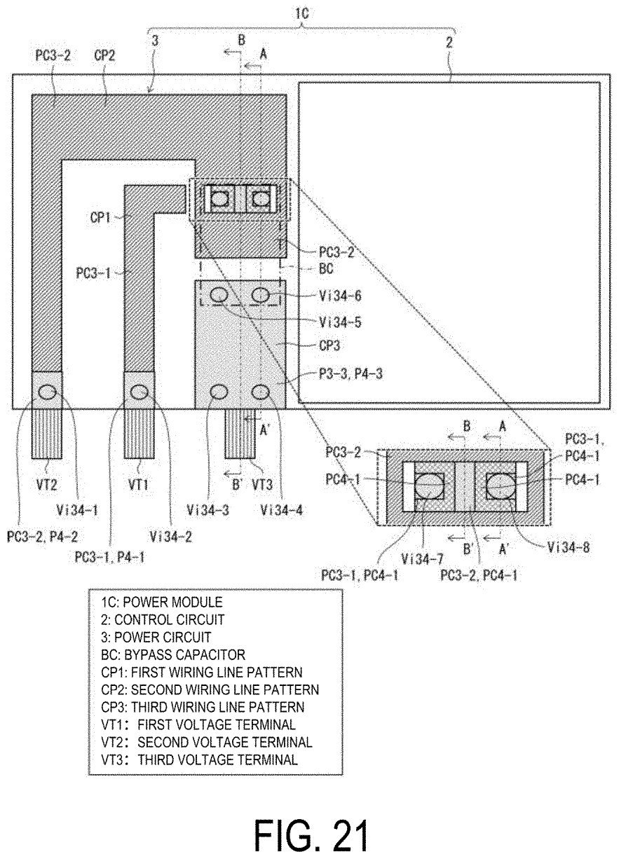

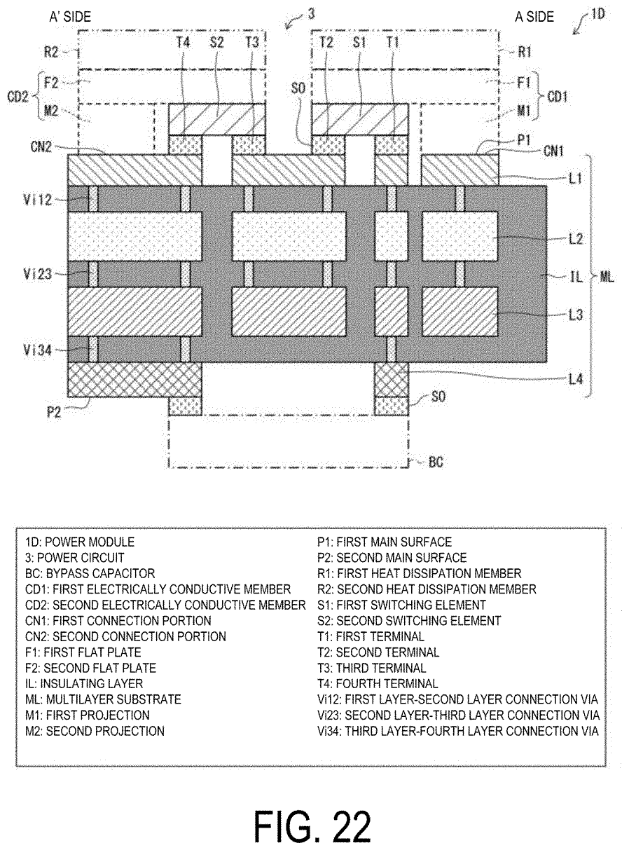

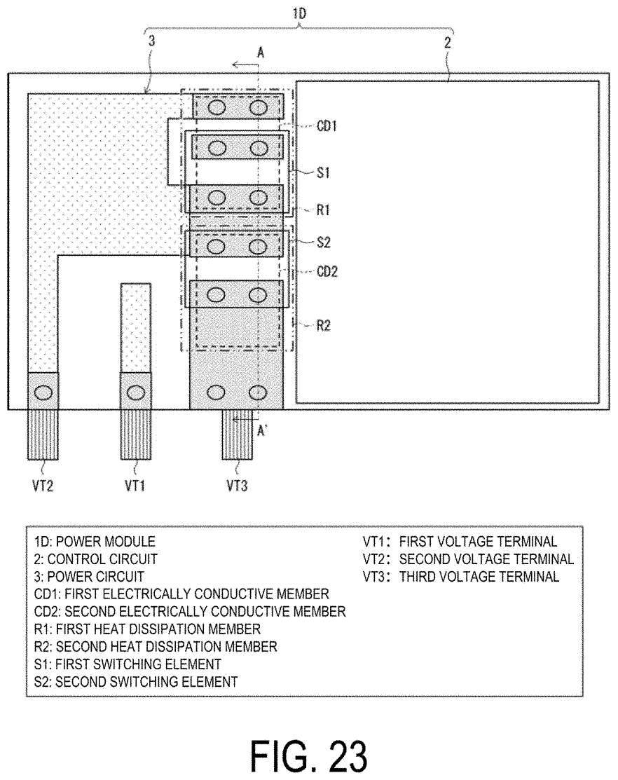

FIG. 17 is a cross-sectional view of the multilayer substrate ML of the power circuit 3 of a power module 1C according to a third embodiment, where a line A-A′ indicated in FIG. 19 is taken as a reference.

FIG. 18 is a cross-sectional view of the multilayer substrate ML of the power circuit 3 of the power module 1C according to the third embodiment, where a line B-B′ indicated in FIG. 19 is taken as a reference. As illustrated in FIGS. 17 and 18, the path of a current flowing through the multilayer substrate ML is indicated by arrows.

FIGS. 19, 20, and 21 are wiring line pattern diagrams of the power module 1C. FIG. 19 illustrates wiring line patterns in the first layer L1 and the second layer L2. FIG. 20 illustrates wiring line patterns in the second layer L2 and the third layer L3. FIG. 21 illustrates wiring line patterns in the third layer L3 and the fourth layer L4.

As illustrated in FIG. 19, in the first layer L1 of the multilayer substrate ML, the second terminal T2 and the first terminal T1 of the first switching element S1, and the third terminal T3 and the fourth terminal T4 of the second switching element S2 are disposed in the stated order.

As illustrated in FIGS. 17 to 21, in order to connect the first terminal T1 of the first switching element S1 to the first voltage terminal VT1, the first wiring line pattern CP1 includes patterns P1-1, PC1-1, PC2-1, PC3-1 and P4-1, first layer-second layer connection vias Vi12-2, Vi12-9 and Vi12-10, second layer-third layer connection vias Vi23-2 Vi23-9 and Vi23-10, and third layer-fourth layer connection vias Vi34-2, Vi34-7 and Vi34-8.

As illustrated in FIGS. 17 to 21, in order to connect the second terminal T2 of the first switching element S1, the third terminal T3 of the second switching element 32 and the second voltage terminal VT2 to one another, the second wiring line pattern CP2 includes patterns P1-2, PC2-2 PC3-2 and P4-2, first layer-second layer connection vias Vi12-1, Vi12-13, Vi12-14, Vi12-11, Vi12-12, Vi12-7 and Vi12-8, second layer-third layer connection vias Vi23-1, Vi23-7, Vi23-8, Vi23-11, Vi23-12, Vi23-13 and Vi23-14, and the third layer-fourth layer connection via Vi34-1.

The third wiring line pattern CP3 is not different from the pattern configuration in the first embodiment.

Due to the change of the wiring line patterns, a current of the power loop flowing through the first switching element S1 and the second switching element S2 is made to flow through a current path having a shape like a figure eight.

By configuring the current path as described above, opposing current paths cancel out magnetic fields due to the current CU flowing through the current paths. This makes it possible to reduce loop inductance, which is the parasitic inductance.

As described above, the power module 1C includes the first switching element S1 and the second switching element S2 mounted on the multilayer substrate ML, and the bypass capacitor BC formed on the multilayer substrate ML so as to form the power loop of the first switching element S1 and the second switching element S2.

The first terminal T1 and the second terminal T2 of the first switching element S1 and the third terminal T3 and the fourth terminal T4 of the second switching element S2 are disposed so as to be structurally aligned in the order of the second terminal T2, the first terminal T1, the third terminal T3, and the fourth terminal T4, as illustrated in FIGS. 17 to 21.

The multilayer substrate ML includes the first wiring line pattern CP1 connecting the first terminal T1 and the bypass capacitor BC, the second wiring line pattern CP2 connecting the second terminal T2 and the third terminal T3, and the third wiring line pattern CP3 connecting the fourth terminal T4 and the bypass capacitor BC.

The power module 1C further includes the first electrically conductive member CD1 that connects a non-mounting surface of the first switching element S1 and the first connection portion CN1 provided on the second wiring line pattern CP2 and located on the side different from the first terminal T1 side with respect to the second terminal T2, and the second electrically conductive member CD2 that connects a non-mounting surface of the second switching element S2 and the second connection portion CN2 provided on the third wiring line pattern CP3 and located on the side different from the third terminal T3 side with respect to the fourth terminal T4.

The first terminal T1 and the third terminal T3 include drain terminals, and the second terminal T2 and the fourth terminal T4 include source terminals.

### Fourth Embodiment

Another embodiment of the disclosure will be described below. Note that, for convenience of explanation, components having a function identical to those in the above-described embodiment will be denoted by the same reference signs, and descriptions of those components will be omitted.

Only portions different from the first embodiment will be described, and a description of other portions will be omitted as these are the same as in the first embodiment.

FIG. 22 is a cross-sectional view of the multilayer substrate ML of the power circuit 3 of a power module 1D according to a fourth embodiment, where a line A-A′ indicated in FIG. 23 is taken as a reference.

As illustrated in FIG. 22, a first heat dissipation member R1 can be disposed by disposing the first electrically conductive member CD1 on the first switching element S1. Similarly, a second heat dissipation member R2 can be disposed by disposing the second electrically conductive member CD2 on the second switching element S2.

As a result, heat generated in the first switching element S1 and the second switching element S2 may be dissipated by the first heat dissipation member R1 and the second heat dissipation member R2 via the first electrically conductive member CD1 and the second electrically conductive member CD2, respectively. This allows the power module 1D to have high heat dissipation properties.

FIG. 23 illustrates a wiring line pattern diagram of the power module 1D. The present embodiment differs from the first embodiment in that the first heat dissipation member R1 is disposed on an upper face of the first electrically conductive member CD1 and the second heat dissipation member R2 is disposed on an upper face of the second electrically conductive member CD2.

As described above, the power module 1D further includes the first heat dissipation member R1 layered on the first electrically conductive member CD1 for heat dissipation of the first switching element S1, and the second heat dissipation member R2 layered on the second electrically conductive member CD2 for heat dissipation of the second switching element S2.

Supplement

The power modules 1, 1A, 1B, and 1D according to a first aspect of the disclosure each include: the first switching element S1 and the second switching element S2 mounted on the multilayer substrate ML; and the bypass capacitor BC formed on the multilayer substrate ML for forming a power loop of the first switching element S1 and the second switching element S2. The first terminal T1 and the second terminal T2 of the first switching element S1, and the third terminal T3 and the fourth terminal T4 of the second switching element 52 are disposed to be aligned in the order of the first terminal T1, the second terminal T2, the third terminal T3, and the fourth terminal T4. The multilayer substrate ML includes the first wiring line pattern CP1 connecting the first terminal T1 and the bypass capacitor BC, the second wiring line pattern CP2 connecting the second terminal T2 and the third terminal T3, and the third wiring line pattern CP3 connecting the fourth terminal T4 and the bypass capacitor BC. The above-mentioned power modules each further include: the first electrically conductive member CD1 connecting the non-mounting surface of the first switching element S1 and the first connection portion CN1 provided on the second wiring line pattern CP2 and located on a side different from the second terminal T2 side with respect to the first terminal T1; and the second electrically conductive member CD2 connecting the non-mounting surface of the second switching element S2 and the second connection portion CN2 provided on the third wiring line pattern CP3 and located on a side different from the third terminal T3 side with respect to the fourth terminal T4.

According to the above-described configuration, the first connection portion CN1 of the first electrically conductive member CD1 is connected at a position on the side different from the second terminal T2 side, and the second connection portion CN2 of the second electrically conductive member CD2 is connected at a position on the side different from the third terminal T3 side, whereby the second terminal T2 and the third terminal T3 may be disposed close to each other, and the power loop can be shortened so as to reduce loop inductance.

The power modules 1, 1A, 1B, and 1D according to second aspect of the disclosure may be such that, in the first aspect, the first switching element S1 and the second switching element S2 are disposed on the first main surface of the multilayer substrate ML, and the bypass capacitor BC is disposed on the second main surface of the multilayer substrate ML on the opposite side to the first main surface.

According to the above-described configuration, since the direction of a current flowing through the first main surface and the direction of a current flowing through the second main surface are reverse to each other, magnetic fields due to the currents cancel each other out, thereby making it possible to reduce the loop inductance.

The power modules 1, 1A, 1B, and 1D according to third aspect of the disclosure may be such that, in the first or second aspect, the multilayer substrate ML includes a plurality of inner layers formed inside the multilayer substrate ML, and the second wiring line pattern CP2 extends through at least one of the plurality of inner layers so as to connect the second terminal T2 and the third terminal T3.

According to the configuration described above, the second terminal T2 and the third terminal T3 are not connected on the first main surface, but may be connected in either the second layer and the third layer that are inner layers. This eliminates the need to ensure a creepage distance because there is no tracking generating path. As a result, the distance between the wiring line patterns of the second terminal T2 and the third terminal T3 on the first main surface may be shortened, and thus the power module may be made smaller.

The power modules 1, 1A, 1B, and 1D according to a fourth aspect of the disclosure may be such that, in the second aspect, the multilayer substrate ML includes a first inner layer formed inside the multilayer substrate ML and a second inner layer formed at a position further separated from the first switching element S1 and the second switching element S2 than the first inner layer, and the second wiring line pattern CP2 extends through the second inner layer to connect the second terminal T2 and the third terminal T3.

According to the above configuration, since the magnetic fields due to the current flowing through the power loop more strongly cancel each other out, the loop inductance, which is the parasitic inductance, may be further reduced.

The power modules 1, 1A, 1B, and 1D according to a fifth aspect of the disclosure may be such that, in any one of the first to fourth aspects, the first electrically conductive member CD1 is connected to the second wiring line pattern on the opposite side to the second terminal T2 side with respect to the first terminal T1.

According to the configuration described above, the distance between the second terminal T2 and the third terminal T3 can be shortened and the loop inductance can be reduced by connecting the first electrically conductive member CD1 with the second wiring line pattern CP2 on the side opposite to the second terminal T2 side with respect to the first terminal T1.

The power modules 1, 1A, 1B, and 1D according to a sixth aspect of the disclosure may be such that, in any one of the first to fifth aspects, the first terminal T1 and the third terminal T3 include drain terminals, and the second terminal T2 and the fourth terminal T4 include source terminals.

According to the above-described configuration, the first switching element S1 and the second switching element S2 may be implemented by FETs.

The power module 1C according to a seventh aspect of the disclosure includes: the first switching element S1 and the second switching element S2 mounted on the multilayer substrate ML; and the bypass capacitor BC formed on the multilayer substrate for forming a power loop of the first switching element S1 and the second switching element S2. The first terminal T1 and the second terminal T2 of the first switching element S1, and the third terminal T3 and the fourth terminal T4 of the second switching element S2 are disposed to be aligned in the order of the second terminal T2, the first terminal T1, the third terminal T3, and the fourth terminal T4. The multilayer substrate ML includes the first wiring line pattern CP1 connecting the first terminal T1 and the bypass capacitor BC, the second wiring line pattern CP2 connecting the second terminal T2 and the third terminal T3, and the third wiring line pattern CP3 connecting the fourth terminal T4 and the bypass capacitor BC. The above-mentioned power module may further include: the first electrically conductive member CD1 connecting the non-mounting surface of the first switching element S1 and the first connection portion CN1 provided on the second wiring line pattern CP2 and located on a side different from the first terminal T1 side with respect to the second terminal T2; and the second electrically conductive member CD2 connecting the non-mounting surface of the second switching element S2 and the second connection portion CN2 provided on the third wiring line pattern CP3 and located on a side different from the third terminal T3 side with respect to the fourth terminal T4.

According to the above-described configuration, the first connection portion CN1 of the first electrically conductive member CD1 is connected at a position on the side different from the first terminal T1 side, and the second connection portion CN2 of the second electrically conductive member CD2 is connected at a position on the side different from the third terminal T3 side. Thus, the first terminal T1 and the third terminal T3 can be disposed close to each other in a range in which a creepage distance can be ensured, and the power loop can be shortened so as to reduce the loop inductance. Furthermore, the current paths opposing each other cancel out magnetic fields due to the current flowing through the current path. This makes it possible to reduce the loop inductance, which is the parasitic inductance.

The power module 1C according to an eighth aspect of the disclosure may be such that, in the seventh aspect, the first terminal T1 and the third terminal T3 include drain terminals, and the second terminal T2 and the fourth terminal T4 include source terminals.

According to the above-described configuration, the first switching element S1 and the second switching element S2 may be implemented by FETs.

The power modules 1, 1A, 1B, 1C, and 1D according to a ninth aspect of the disclosure may each further include, in any one of the first to eighth aspects, the first heat dissipation member R1 layered on the first electrically conductive member CD1 for heat dissipation of the first switching element S1, and the second heat dissipation member R2 layered on the second electrically conductive member CD2 for heat dissipation of the second switching element S2.

According to the above-described configuration, the heat generated in the first switching element S1 and the second switching element S2 can be dissipated by the first heat dissipation member R1 and the second heat dissipation member R2 via the first electrically conductive member CD1 and the second electrically conductive member CD2, respectively. This allows the power modules 1, 1A, 1B, 1C, and 1D to have high heat dissipation properties.

An aspect of the disclosure is not limited to each of the above-described embodiments. It is possible to make various modifications within the scope of the claims. An embodiment obtained by appropriately combining technical elements each disclosed in different embodiments falls also within the technical scope of the aspect of the disclosure. Furthermore, technical elements disclosed in the respective embodiments may be combined to provide a new technical feature.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A power module comprising:
a first switching element and a second switching element mounted on a multilayer substrate; and
a bypass capacitor formed on the multilayer substrate for forming a power loop of the first switching element and the second switching element,
wherein a first terminal and a second terminal of the first switching element, and a third terminal and a fourth terminal of the second switching element are disposed to be aligned in an order of the first terminal, the second terminal, the third terminal, and the fourth terminal,
the multilayer substrate includes,
a first wiring line pattern connecting the first terminal and the bypass capacitor,
a second wiring line pattern connecting the second terminal and the third terminal, and
a third wiring line pattern connecting the fourth terminal and the bypass capacitor, and
the power module further includes,
a first electrically conductive member connecting a non-mounting surface of the first switching element and a first connection portion provided on the second wiring line pattern and located on a side different from the second terminal side with respect to the first terminal, and
a second electrically conductive member connecting a non-mounting surface of the second switching element and a second connection portion provided on the third wiring line pattern and located on a side different from the third terminal side with respect to the fourth terminal.

2. The power module according to claim 1,
wherein the first switching element and the second switching element are disposed on a first main surface of the multilayer substrate, and
the bypass capacitor is disposed on a second main surface of the multilayer substrate on an opposite side to the first main surface.

3. The power module according to claim 1,
wherein the multilayer substrate includes a plurality of inner layers formed inside the multilayer substrate, and
the second wiring line pattern extends through at least one of the plurality of inner layers so as to connect the second terminal and the third terminal.

4. The power module according to claim 1,
wherein the multilayer substrate includes a first inner layer formed inside the multilayer substrate and a second inner layer formed at a position further separated from the first switching element and the second switching element than the first inner layer, and
the second wiring line pattern extends through the second inner layer to connect the second terminal and the third terminal.

5. The power module according to claim 1,
wherein the first electrically conductive member is connected to the second wiring line pattern on a side opposite to the second terminal side with respect to the first terminal.

6. The power module according to claim 1,
wherein the first terminal and the third terminal include drain terminals, and
the second terminal and the fourth terminal include source terminals.

7. A power module comprising:
a first switching element and a second switching element mounted on a multilayer substrate; and
a bypass capacitor formed on the multilayer substrate for forming a power loop of the first switching element and the second switching element,
wherein a first terminal and a second terminal of the first switching element, and a third terminal and a fourth terminal of the second switching element are disposed to be aligned in an order of the second terminal, the first terminal, the third terminal, and the fourth terminal,
the multilayer substrate includes,
a first wiring line pattern connecting the first terminal and the bypass capacitor,
a second wiring line pattern connecting the second terminal and the third terminal, and
a third wiring line pattern connecting the fourth terminal and the bypass capacitor, and
the power module further includes,
a first electrically conductive member connecting a non-mounting surface of the first switching element and a first connection portion provided on the second wiring line pattern and located on a different side from the first terminal side with respect to the second terminal, and
a second electrically conductive member connecting a non-mounting surface of the second switching element and a second connection portion provided on the third wiring line pattern and located on a different side from the third terminal side with respect to the fourth terminal.

8. The power module according to claim 7,
wherein the first, terminal and the third terminal include drain terminals, and
the second terminal and the fourth terminal include source terminals.

9. The power module according to claim 1, further comprising:
a first heat dissipation member layered on the first electrically conductive member for heat dissipation of the first switching element; and
a second heat dissipation member layered on the second electrically conductive member for heat dissipation of the second switching element.
